(19) United States
(12) Patent Application Publication
(10) Pub. No.: US 2020/0219698 A1
(43) Pub. Date: Jul. 9, 2020

(54) RECURSIVE COILS FOR INDUCTIVELY COUPLED PLASMAS

(71) Applicant: Applied Materials, Inc., Santa Clara, CA (US)

(72) Inventors: Zheng John YE, Santa Clara, CA (US); Abhijit KANGUDE, Fremont, CA (US); Luke BONECUTTER, Cedar Park, TX (US); Rupankar CHOUDHURY, BANGALORE (IN); Jay D. PINSON, II, San Jose, CA (US)

(21) Appl. No.: 16/678,081

(22) Filed: Nov. 8, 2019

(30) Foreign Application Priority Data
Jan. 8, 2019 (IN) 201941000851

(51) Int. Cl. H01J 37/32; H01L 21/67; H01L 21/683

(52) U.S. Cl. CPC H01J 37/3211; H01J 37/32183; H01J 37/32724; H01J 2237/002; H01L 21/67167; H01L 21/6833; H01J 37/32899

(57) ABSTRACT

Embodiments of the present disclosure generally relate to a semiconductor processing apparatus. More specifically, embodiments of the disclosure relate to generating and controlling plasma. A process chamber includes a chamber body that includes one or more chamber walls and defines a processing region. The process chamber also includes two or more inductively driven radio frequency (RF) coils in a concentric axial alignment, the RF coils arranged near the chamber walls to strike and sustain a plasma inside the chamber body, where at least two of the two or more RF coils are in a recursive configuration.

### CROSS-REFERENCE TO RELATED APPLICATION

This application claims benefit of Indian Provisional Patent Application Serial No. 201941000851, filed Jan. 8, 2019, which is incorporated herein in its entirety.

### BACKGROUND OF THE DISCLOSURE

### Field of the Disclosure

Implementations described herein generally relate to an apparatus and method for processing substrates. More particularly, the present disclosure relates to methods and apparatus for generating and controlling plasma, for example inductively coupled coils, used with plasma chambers. The methods and apparatus can be applied to semiconductor processes, for example, plasma deposition and etch processes and other plasma processes used to form integrated circuits.

### Description of the Related Art

Inductively coupled plasma (ICP) process chambers generally form plasma by inducing ionization in a process gas disposed within the process chamber via one or more inductive coils disposed outside of the process chamber. The inductive coils are disposed externally and separated electrically from the process chamber by, for example, a dielectric lid. When radio frequency (RF) current is fed to the inductive coils via an RF feed structure from an RF power source, an inductively coupled plasma can be formed inside the process chamber from a magnetic field generated by the inductive coils.

For substrate processing, a single spiral inductive coil develops a voltage drop throughout the coil length, and the electromagnetic field coupling between neighboring turns of the coil causes in-phase or out-of-phase interference leading to current distribution variation from one end to the other. This can lead to non-concentric field patterns that produce substandard results.

Therefore, there is a need in the art for an improved coil.

### SUMMARY OF THE DISCLOSURE

Embodiments of the present disclosure generally relate to semiconductor processing apparatus. More specifically, embodiments of the disclosure relate to an improved coil. In one embodiment, a process chamber includes a chamber body that includes one or more chamber walls and defines a processing region. The process chamber also includes two or more inductively driven RF coils in a concentric axial alignment, the RF coils arranged near the chamber walls to strike and sustain a plasma inside the chamber body, where at least two of the two or more RF coils are in a recursive configuration.

In another embodiment, a process chamber includes a chamber body that includes one or more chamber walls and defines a processing region. The process chamber also includes an electrostatic chuck comprising a positive electrode and a negative electrode, where a complete circuit is formed between the positive and negative electrodes to provide constant charging to the electrodes. The process chamber also includes two or more inductively driven RF coils in a concentric axial alignment, the RF coils arranged near the chamber walls to strike and sustain a plasma inside the chamber body, where at least two of the two or more RF coils are in a recursive configuration.

In another embodiment, a radio frequency (RF) coil configuration is disclosed that includes two or more RF coils comprising a concentric axial alignment and each having an RF input line and an RF output line, wherein for each input line, there are multiple output lines each having the same length.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 schematically illustrates a clustered substrate processing system according to one embodiment.

FIGS. 2A, 2B, and 2C illustrate example implementations of RF coils according to various embodiments.

FIG. 3A, 3B, and 3C illustrate different coil configurations according to various embodiments.

FIGS. 4A-4F illustrate flat coil configurations according to various embodiments.

FIG. 5 illustrates an equivalent circuit of a recursive ICP system, according to an embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present disclosure generally relate to semiconductor processing apparatus and methods. More specifically, embodiments of the disclosure relate to a method of constructing an RF coil that generates concentric field patterns by using multiple parallel-fed coils. The parallel-fed coils are in a recursive configuration as disclosed herein. The term “recursive” is defined as for every RF “in” transmission line, there are multiple RF “out” transmission lines, and each “out” transmission line traces back to the “in” transmission line with the same length. Alternatively or additionally, the term “recursive” is defined as all “out” transmission lines are electrically synchronized with respect to each other. By splitting the RF coil into multiple sections of parallel connected coils, any asymmetry in the azimuthal direction will repeat periodically at each split such that the overall electromagnetic field variation is reduced on spatial average. Field uniformity can be improved in the radial and azimuthal direction. The number of sections can be as small as two, up to any even or odd number. The coils form a configuration where each of the coils takes on a spiral shape of multiple turns, rotated by 360 degrees/N, where N is an integer, which forms a repetitive pattern with respect to the center axis of the substrate in the processing chamber. The coils can be connected in series or in parallel, or the coils can be connected in a group of several in series forming several groups that are then connected in series, or in parallel, and so on. A higher repetition rate leads to better uniformity compared to a lower repetition rate. Additionally, an impedance matching network that drives the recursive coil system is described.

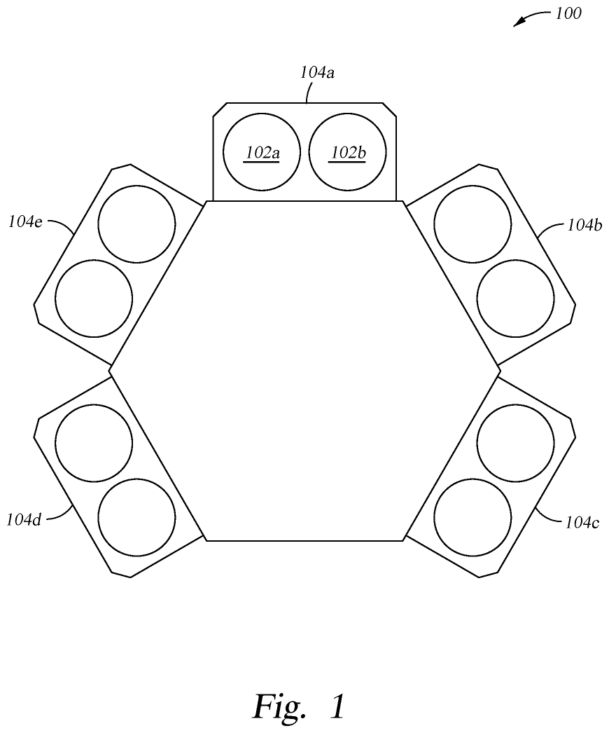

FIG. 1 is a schematic representation of a clustered substrate processing system 100 according to one embodiment described herein. Process chambers 102a and 102b are illustrated in a twin-chamber configuration. A housing defines a process chamber, a gas delivery system, a high-density plasma generating system, a substrate holder, and a controller. The housing includes a side wall and a dome-like enclosure, both made of dielectric materials. The high-density plasma generating system is coupled with the process chamber. The substrate holder is disposed within the process chamber and supports a substrate during processing. The controller controls the gas delivery system and the high-density plasma generating system.

Two identical chambers, such as process chambers 102a and 102b, can be arranged side-by-side as illustrated in FIG. 1. Arrangements of a shared gas delivery system, high-density plasma generating system, substrate holder, and controller can be made to optimize throughput, film quality, and/or cost considerations. Multiple twin chamber workstations, such as workstations 104a through 104e, can be configured as shown to form a clustered substrate processing system. Five twin chambers are illustrated in this embodiment, but other embodiment may have more or fewer twin chambers.

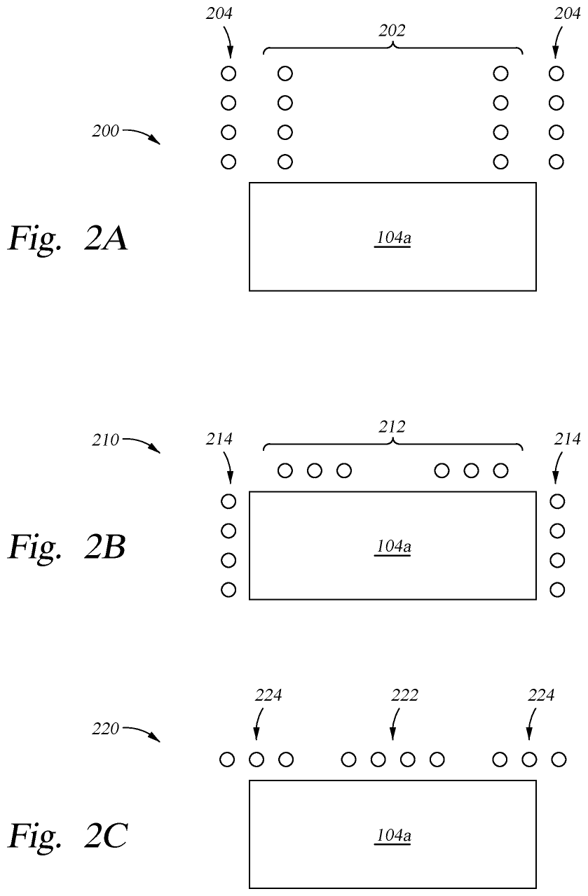

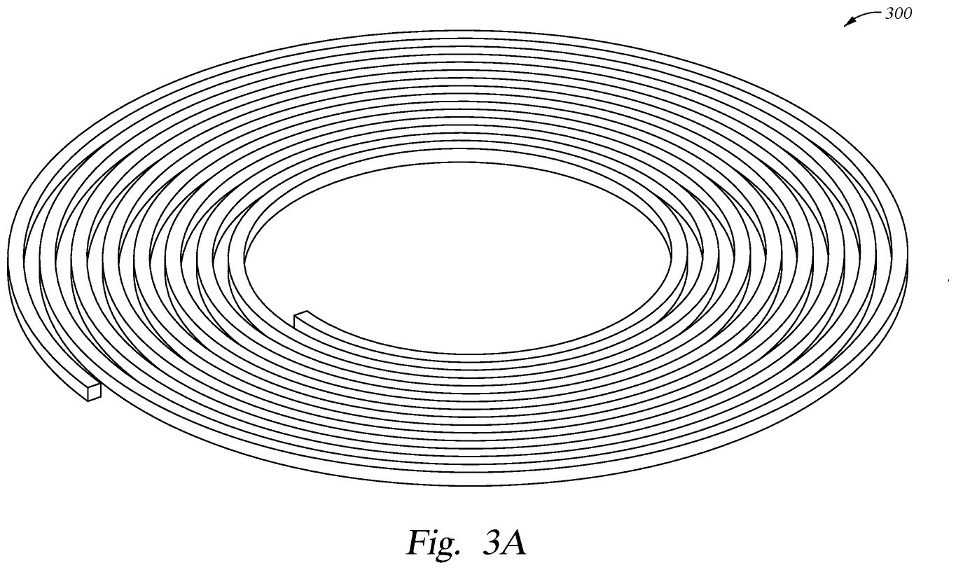

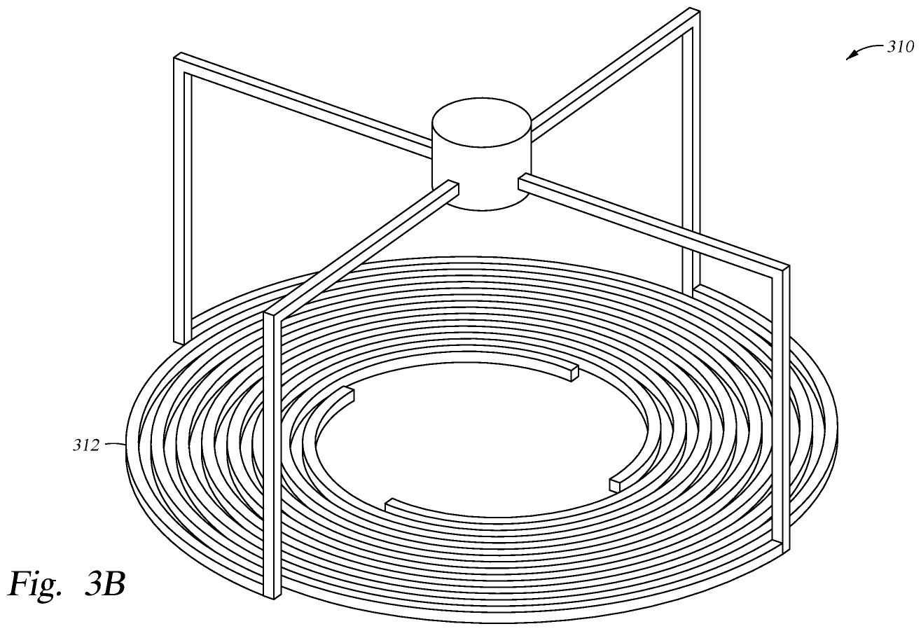

FIGS. 2A, 2B, and 2C illustrate example implementations of RF coils according to various embodiments. Three configurations are shown using workstation 104a as an example. Each of the coils described in these figures is comprised of a single conductor of circular or rectangular cross-section area that forms multiple turns or partial turns. The ends of the coils are used to feed RF currents. Circular cross-section areas are illustrated here, but the cross sections may be rectangular in other embodiments. In addition, the RF coils can be hollow to allow for coolant flow inside the coils without restriction.

In configuration 200 illustrated in FIG. 2A, two vertical helix RF coils are illustrated in concentric axial alignment but with different diameters. That is, a cross section of inner coil 202 is illustrated. A cross section of outer coil 204 is also illustrated. Inner coil 202 has a smaller diameter than outer coil 204. The cross sections of coils 202 and 204 illustrated here show that each coil has four turns, represented by the eight dots for each coil.

A second configuration is illustrated in configuration 210 in FIG. 2B. A top coil 212 is illustrated in cross section on top of workstation 104a. The top coil has three turns, as illustrated by the six dots representing the cross section. A side coil 214 is illustrated on the sides of workstation 104a. The side coil 214 has four turns as shown. This configuration therefore illustrates one vertical helix and another flat, spiral-shaped coil of concentric axial alignment.

A third configuration is illustrated in configuration 220 as shown in FIG. 2C. In this configuration, two flat recursive coils are shown, an inner coil 222 and an outer coil 224. Coils 222 and 224 are flat, spiral-shaped coils of concentric axial alignment. Both coils are on the same plane instead of surrounding the plasma in this configuration. The inner coil 222 is shown with four turns in this embodiment. The outer coil 224 is shown with three turns in this embodiment. Although not shown, an embodiment without the inner coil 222 may also be implemented.

With respect to the embodiments illustrated in FIGS. 2A to 2C, RF current is delivered into one end of the coil which is known as the input. The RF current exits the coil through the other end, known as the output. Along the entire coil length there is a certain current and voltage distribution that propagates away from the coil, induces the electric and magnetic field through the dielectric chamber wall, and strikes and sustains the plasma inside the chamber under appropriate gas delivery and pressure conditions.

For substrate processing, the electromagnetic field generated by the inductive coils exhibits concentric patterns with respect to the center axis of the substrate. In cases where the axis of the coils is concentric with respect to the substrate axis, the electromagnetic field that the coil generates is not necessarily concentric due to electromagnetic field propagation along the coil path and boundary conditions that are not necessarily concentric.

In embodiments described herein, RF coils are disclosed that generate concentric field patterns by using multiple parallel-fed coils. Splitting the coil into multiple sections of parallel connected coils allows for asymmetry in the azimuthal direction to repeat periodically at each split, such that the overall field variation is reduced on spatial average.

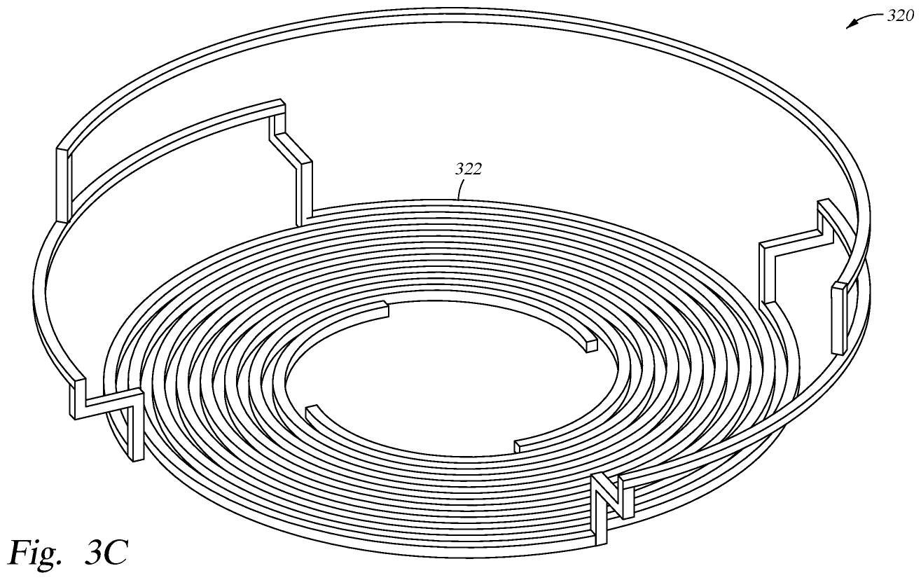

FIGS. 3A, 3B, and 3C illustrate different coil configurations. FIG. 3A illustrates a single RF coil 300 forming a 4.5 turn spiral. A single spiral coil such as coil 300 develops a voltage drop throughout the coil length. In addition, the electromagnetic field coupling between the neighboring turns causes in-phase or out-of-phase interference leading to current distribution variation from one end of the coil to the other end. However, by symmetrically splitting the coil into multiple sections of parallel connected coils, any asymmetry in the azimuthal direction repeats itself periodically at each split, such that the overall field variation is reduced on spatial average.

FIG. 3B illustrates a configuration 310 with a set of parallel flat coils 312 with a symmetric RF feed. A four-way coil split is shown. FIG. 3C illustrates a configuration 320 with a set of vertical helix coils with a symmetric RF feed, also in a four-way coil split. In general, the more splits there are, the less the rippling effect from the coils. The number of splits can go as small as two, up to any number.

Additionally, each split may have a length that is shorter or longer than one full length. For example, a split can have a half turn, one full turn, 1.5 turns, and so on, such that the base coil can replicate itself if rotated around its axis. For example, the coil rotates 180 degrees if replicated by 2, 120 degrees if replicated by 3, 90 degrees if replicated by 4, etc.

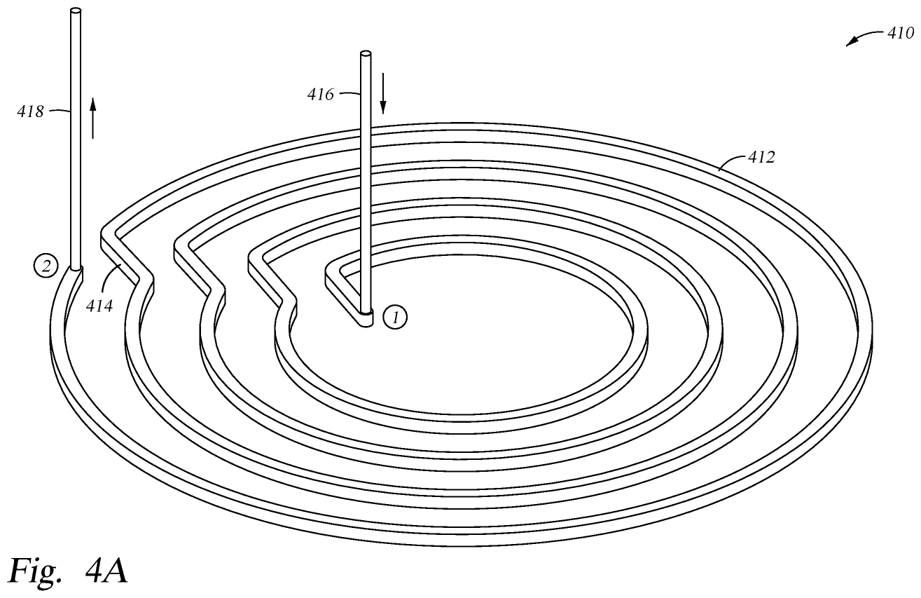

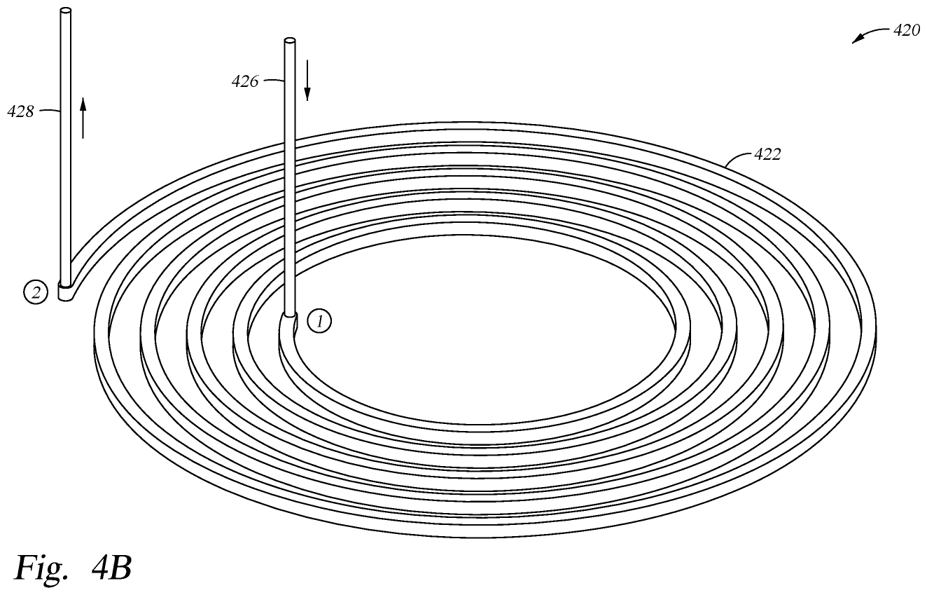

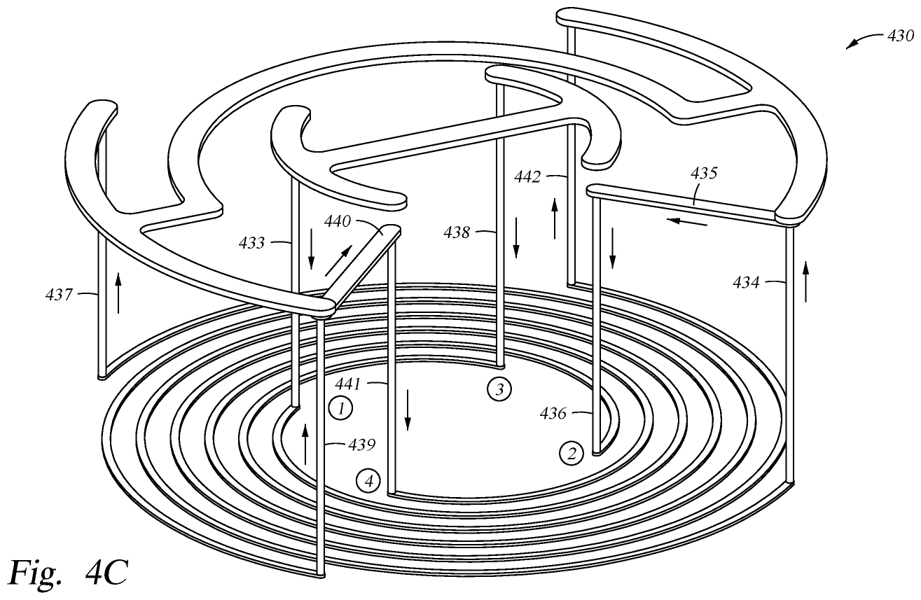

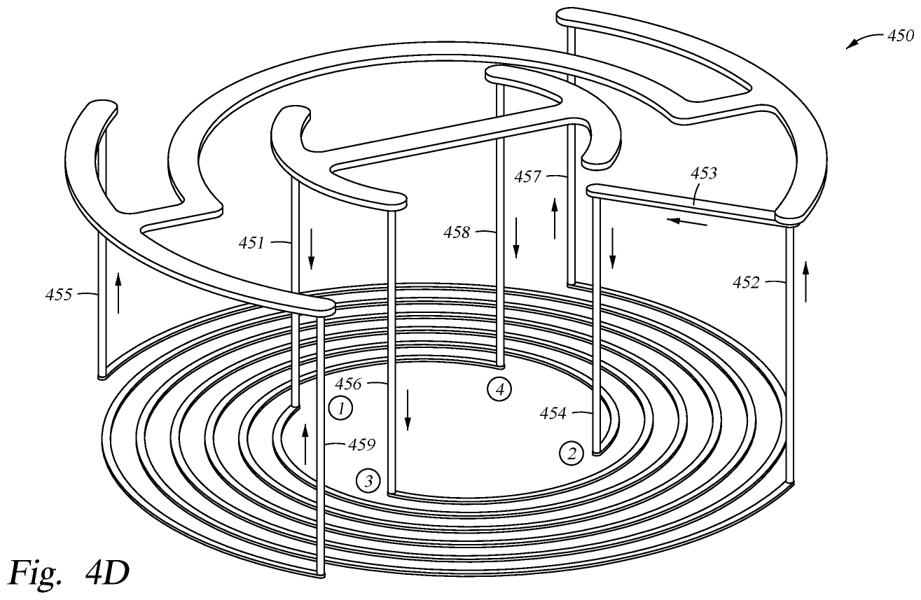

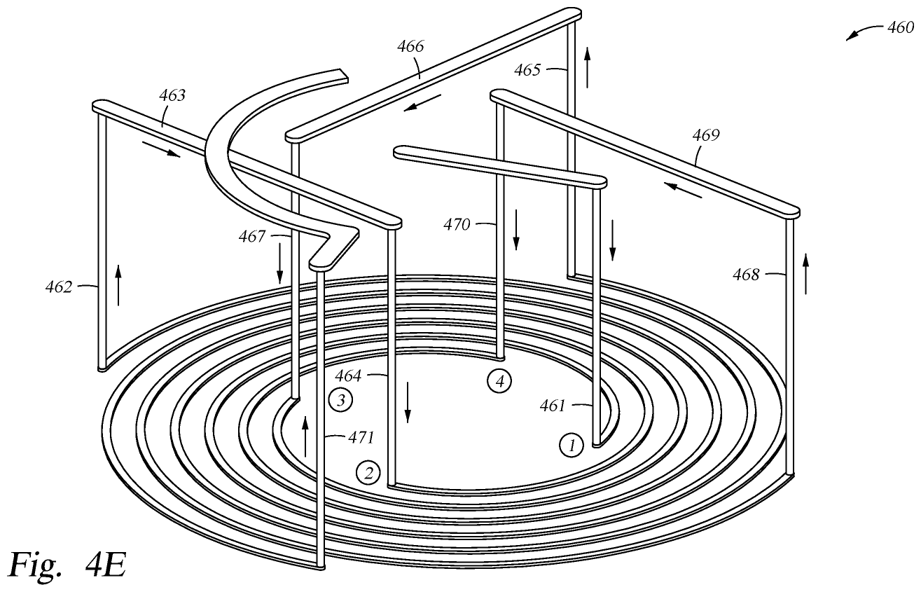

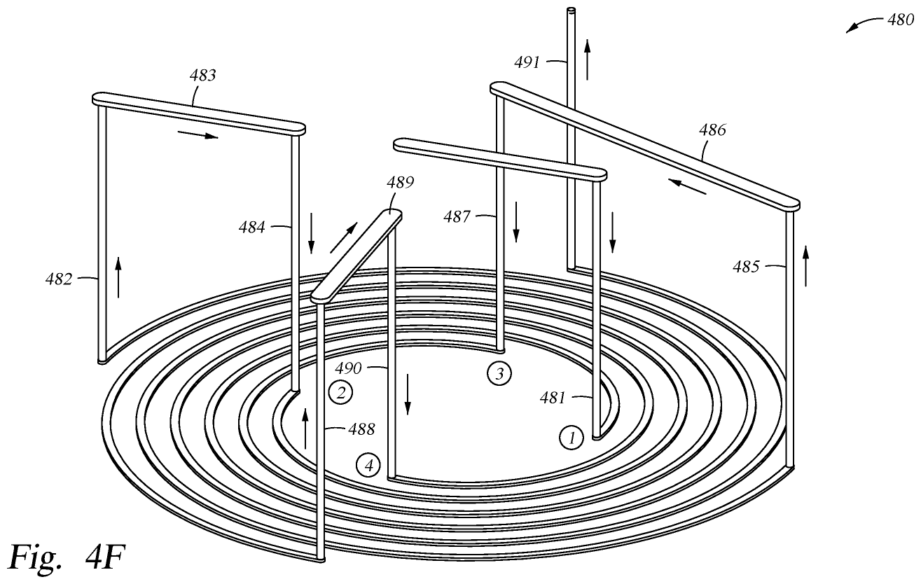

FIG. 4A illustrates a flat coil configuration to carry the RF current for plasma coupling. Configuration 410 illustrates a single coil 412 with 4 turns between the input and output of the coil. Coil 412 takes the shape of concentric rings with kinks on a small portion of each ring to make the connection to the next ring of the coil. One of the kinks 414 is labeled, and four are illustrated in the figure. Current enters along path 1, or RFᵢₙ labeled 416, into the center of the coil. An arrow shows the direction of current flow. Current exits the coil along path 2, or RFₒᵤₜ labeled 418, on the left edge of the figure. As shown, the current makes four turns around the coil. In the portions of the coil 412 where the kinks 414 are located, the coil direction is not concentric as are the other portions of the coil.

In FIG. 4B, configuration 420 illustrates a coil 422 with five turns between the input and output of the coil. Coil 422 is a spiral-shaped coil. Current enters along path 1, or RFᵢₙ labeled 426, into the center of the coil. An arrow shows the direction of current flow. Current exits the coil along path 2, or RFₒᵤₜ labeled 428.

FIG. 4C illustrates a flat coil configuration according to an embodiment. This embodiment may be referred to as a 2×2 configuration. That is, two coils are connected together to form a first set and two other coils are connected together to form a second set. The first set and the second set can then be connected. In this case the sets are connected in parallel.

Configuration 430 is illustrated in FIG. 4C. Four coils are labeled 1, 2, 3, and 4. Coils 1 and 2 are connected together, while coils 3 and 4 are connected together. The set of coils 1 and 2 are in parallel with the set of coils 3 and 4.

In operation, current enters coil 1 along path 433 or RFᵢₙ, illustrated with an arrow going down into the coil. The current flows through coil 1 and then comes up along the right side of the figure on path 434. Current then travels along path 435 and 436 and down into coil 2. Current flows through coil 2 and then up through path 437 shown on the left side of the figure.

Meanwhile, current is also flowing through coils 3 and 4, which are in parallel to coils 1 and 2. Current flows down path 438 into coil 3. After flowing through coil 3, current flow up through path 439. The current then flows down across path 440 and into coil 4 via path 441. Finally, current flows out of coil 4 via path 442 or RFₒᵤₜ.

FIG. 4D illustrates configuration 450. Configuration 450 is also a 2×2 configuration. Coils 1 and 2 are connected together, while coils 3 and 4 are connected together. The set of coils 1 and 2 are in parallel with the set of coils 3 and 4.

In operation, current enters coil 1 along path 451 or RFᵢₙ, illustrated with an arrow going down into the coil. The current flows through coil 1 and then comes up along the right side of the figure on path 452. Current then travels along path 453 and 454 and down into coil 2. Current flows through coil 2 and then up through path 455 shown on the left side of the figure.

Meanwhile, current is also flowing through coils 3 and 4, which are in parallel to coils 1 and 2. Current flows down path 456 into coil 3. After flowing through coil 3, current flow up through path 457. The current then flows into coil 4 via path 458. Finally, current flows out of coil 4 via path 459 or RFₒᵤₜ.

FIGS. 4E and 4F illustrate additional configurations, 460 and 480. In each of these configurations, the coils are connected in series. In configuration 460 in FIG. 4E, current flows into coil 1 via path 461. The coil makes 1.5 turns in this example, and current flows out of coil 1 via path 462. Current flows along path 463 and down path 464 into coil 2. Coil 2 also makes 1.5 turns and current flows out of coil 2 via path 465.

After leaving coil 2, current flows along path 466 and down path 467 to coil 3. Current flows through the 1.5 turns of coil 3 and then up path 468 along the right edge of the figure, and across path 469. Then current flows down path 470 to coil 4. The current flows through the 1.5 turns of coil 4 and out of coil 4 via path 471 (RFₒᵤₜ).

Configuration 480 is illustrated in FIG. 4F. Configuration 480 is similar to configuration 460, but the connections between the coils are slightly different. Current flows into coil 1 via path 481 (RFᵢₙ). The coils also make 1.5 turns in this example, and current flows out of coil 1 via path 482. Current flows along path 483 and down path 484 into coil 2. Coil 2 also makes 1.5 turns and current flows out of coil 2 via path 485.

After leaving coil 2, current flows along path 486 and down path 487 to coil 3. Current flows through the 1.5 turns of coil 3 and then up path 488, and across path 489. Then current flows down path 490 to coil 4. The current flows through the 1.5 turns of coil 4 and out of coil 4 via path 491 (RFₒᵤₜ).

As described above, the four coils illustrated in the embodiments of FIGS. 4C to 4F can be connected in series, in parallel, or in a series connection with two legs forming two sets which are then connected in parallel connection. Another connection embodiment is to form a parallel connection for two coils, and then the sets of parallel coils are connected in parallel to one another. As long as the individual coils are in recursive arrangement, the magnetic field generated by the coils will repeat itself at each repetition, resulting in a periodic pattern for the magnetic field along the azimuthal direction. In general, the more repetition that is present, the more uniform the field will be in the azimuthal direction. In the examples described above, the configurations in FIGS. 4C to 4F yield better field uniformity in the radial and azimuthal direction than the configurations in FIGS. 4A and 4B.

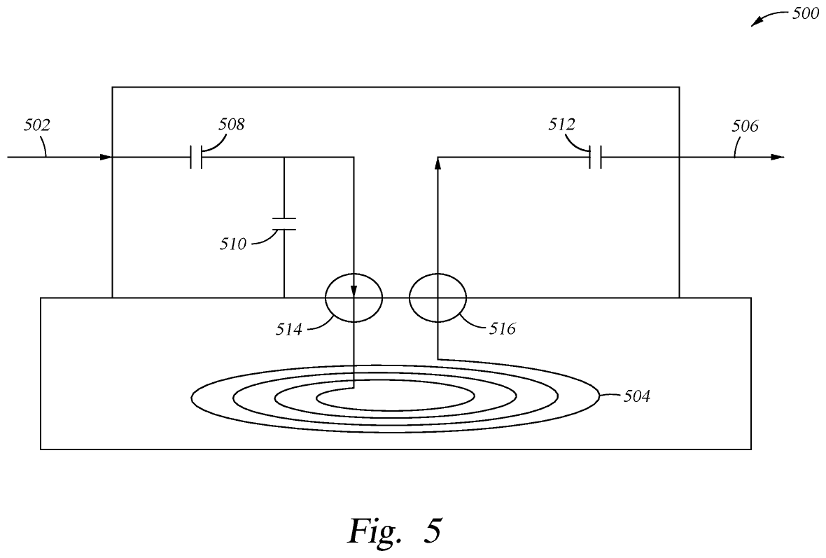

FIG. 5 illustrates an example impedance matching network 500 according to an embodiment. An impedance matching network is used to drive a particular recursive coil configuration using an RF generator with a 50 Ohm characteristic impedance. The RF generated signal 502 enters the impedance matching network, travels through the coils 504 where plasma is generated, and then travels out to ground 506. A three-capacitor impedance matching network 500 is illustrated here. Load capacitor 508, tuning capacitor 510, and return capacitor 512 couple to the coil power input and coil power output to generate 50 Ohm impedance without reactance, if the correct values are chosen for the three capacitors. The impedance matching network 500 matches the coils 504, which is not a 50 Ohm load, with the generator which is a 50 Ohm load. Coils 504 are modeled as small resistor and a large inductor, with real and imaginary parts Rₛ+jωL. The impedance matching network 500 converts this Rₛ+jωL into the equivalent of a 50 Ohm circuit. When matched with impedance matching network 500, the generator can maximize output.

The values for the set of capacitors 508, 510, and 512 are affected by the coil load impedance. Increasingly higher values of the capacitors are utilized for lower resistance and lower inductance values. The precise resistance and inductance values are affected by the individual recursive coils 504 and the way the coils 504 are connected, either in serial, parallel, or a combination of such connections as described above. In general, coil resistance is reduced when the coils are connected in parallel and increases when connected in series, with a similar effect for the inductance.

The values for the set of capacitors 508, 510, and 512 are also affected by the RF frequency. Typical frequency values are 350 kHz, 2 MHz, 13 MHz, 13.56 MHz, 25 MHz, and 60 MHz. Any other suitable values for the frequency may be used in embodiments described herein.

The series resistance and inductance of the coils 504 affect the voltage and current delivered to the coils and the power coupled to the plasma. Generally, the series resistance controls the current and the inductance controls the voltage of coils 504. The resulting voltage and current of coils 504 place limits on the capacitors, and the voltage and current ratings of the capacitors are used in the impedance matching network 500 for a given delivered power specification, as well as the power loss inherited from the matching network.

Described herein is apparatus and methods of precisely measuring the coil load impedance with the plasma load. A pair of identical RF voltage and current sensors (sensors 514 and 516) are placed at the power input and output ends of the coils 504 to dynamically measure the voltage and current waveform in real time, after calibrating the sensors 514 and 516 with a known voltage and current generated by running a known power into a short circuit by-passing strap and then into a 50 Ohm dummy load. Sensor 514 is referred to as the RFᵢₙ sensor and sensor 516 is referred to as the RFₒᵤₜ or the return sensor. The by-passing RF strap, if properly designed, generates no reflected power toward the 50 Ohm RF generator and carries the known voltage and current going through both sensors 514 and 516. The sensors 514 and 516 would then see the voltage and current generated by the coils 504 with the plasma load at the power input and output end, and would be used to calculate the load impedance in real time.

Magnetic field distribution of the recursive coils configuration is dependent on the distance away from the coils. The most uniform magnetic field positions, in some embodiments, may not be close or far away from the coils, but in a “predetermined spot or spots forming a range for the best field uniformity. In a similar fashion, the best uniformity for plasma density may also occur at a sweet spot or spots, and a substrate motion system may be used to find such spots. Therefore a vertical motion mechanism can be used in some embodiments to find the optimal uniformity for deposition, etch, and treatment results.

In another aspect of certain embodiments, several groups of recursive coils, each group driven by a separate RF matching network and generator, are used to generate a favorable overlay from each of the recursive coil groups that will further optimize the plasma uniformity. Multiple groups of recursive coils may be used to dynamically tune the plasma center-to-edge profile by controlling the power delivered to each of the recursive coil groups.

In some embodiments, an electrostatic chuck (ESC) uses a Johnson-Rahbek ESC that operates in the temperature range of about 100° C. to about 700° C. for thin film deposition, etch, and treatment applications. The operating temperature may be controlled in closed loop based upon the real-time temperature measurements at a given time, or over a time period in which the operating temperature is substantially consistent. The operating temperature may also change to follow a predefined pattern in some embodiments. The temperature variation across the surface of the ESC is substantially small, for example less than 10% with respect to the mean operating temperature.

In some embodiments, the ESC may incorporate one or more embedded electrodes forming closed loop electrical circuitry to provide opposite charge polarity between the back side of the substrate and the top surface of the ESC. The closed loop may include a plasma sustained between the substrate and the conductive walls that contain the ESC itself as well as other supporting parts.

In some embodiments, the ESC is composed of a bulk dielectric material of appropriate thermal, mechanical, and electrical properties to provide superior chucking performance. The bulk dielectric material may comprise primarily aluminum nitride sintered under greater than 1000° C., forming a body of the ESC of predefined geometry. The ESC body may be machined and polished to comply with the predefined geometry and surface conditions. In particular to the electrical properties, the volume resistivity of the dielectric materials is controlled to fall in the range of about 1×10⁷ ohm-cm to about 1×10¹⁶ ohm-cm, depending upon the operating temperature. A lower level of the volume resistivity enables electrical charge migration from the embedded chucking electrode towards the top surface of the ESC so that the surface charge may induce the same amount of opposite polarity charge on the back side of the substrate. The opposite polarity charges can be sustained against discharging so as to generate continuous Coulombic attraction forces that clamp the substrate against the ESC.

In some embodiments, the ESC may incorporate embedded heater elements forming a specific pattern, or several specific patterns occupying different zones inside the ESC body. The heater elements may be powered with one or multiple DC power supplies or powered directly using the AC lines.

In some embodiments, the ESC may incorporate a network of electrical protection circuitry to protect against potential harm due to radio frequency and lower frequency voltage and current that may be present near or coupled from elsewhere to the ESC. The protection circuitry may consist of fuses, switches, discharge paths to ground, current limiting devices, voltage limiting devices, and filtering devices to achieve sufficient attenuation of any potentially harmful voltage and current that may be distributed within one frequency exclusively, or spreading across a broad frequency spectrum from DC, AC line frequencies, RF frequencies, up to the VHF frequencies.

In some embodiments, the top surface of the ESC may include surface contact features forming a uniform or non-uniform pattern upon clamping. The pattern may present to the back side of the substrate as full coverage or partial coverage of the entire area of the back side of the substrate. The contacting surface of the pattern may have micro roughness as a result of machining and polishing, and may contain a coating of substantially the same material as the ESC body, or different materials, of the appropriate thickness. The surface contact features may be in the form of distinct islands, or mesa structures having a top surface configured to be in contact with the substrate back side, with either identical or different shapes of the islands, and distributed in either uniform density or non-uniform density across the ESC surface. The top surface may also contain blocking features whose top surface is not in contact with the substrate during processing, and may be elevated to a comparable level or higher than the substrate level to prevent undesired substrate movement during substrate processing, or prior to the substrate being chucked. The blocking features may be equally spaced apart around the circumference of the ESC body, or may be extended into a continuous, ring type of structure that may be detachable to the ESC.

In an application that chucks the substrate without the plasma acting as the return circuit, embodiments herein include a method of implementing bipolar e-chucking of the Johnsen-Rahbek type where more than one chucking electrode is embedded in aluminum nitride ceramic heaters. The minimum number of the embedded electrodes is two, one for the positive charges and one for the negative charges. Between the two electrodes a complete DC circuit with return is formed to provide constant charging to the respective electrodes. The electrodes may comprise multiple pieces of any particular pattern or shape. For example, an electrode may be comprised of two halves, interdigital, serpentine, or segmented in the radial or azimuthal direction as desired to provide uniformity.

Upon applying to and between the electrodes, Coulombic attraction between the positive and the negative electrode can generate sufficient chucking force to keep the substrate attached to the ceramic heater surface. De-chuck occurs after removing the applied voltage, while the remaining charge will deplete through the ceramic material that is semi-conductive under high temperature.

While the foregoing is directed to embodiments of the present disclosure, other and further embodiments of the disclosure may be devised without departing from the basic scope thereof, and the scope thereof is determined by the claims that follow.

1. A process chamber, comprising:
a chamber body comprising one or more chamber walls and defining a processing region; and
two or more inductively driven radio frequency (RF) coils comprising a concentric axial alignment, the RF coils arranged near the chamber walls to strike and sustain a plasma inside the chamber body, wherein at least two of the two or more RF coils are in a recursive configuration.

2. The process chamber of claim 1, wherein the RF coils comprise four coils.

3. The process chamber of claim 2, wherein each of the four RF coils are in a series connection.

4. The process chamber of claim 2, wherein each of the four RF coils are in a parallel connection.

5. The process chamber of claim 2, wherein a first set of two RF coils are in a series connection and a second set of two RF coils are in a separate series connection, and the first set is in parallel to the second set.

6. The process chamber of claim 2, wherein a first set of two RF coils are in a parallel connection and a second set of two RF coils are in a separate parallel connection, and the first set is in parallel to the second set.

7. The process chamber of claim 1, wherein each RF coil comprises a single conductor that forms multiple turns or partial turns.

8. The process chamber of claim 7, wherein each RF coil is hollow to allow for coolant flow inside the coil.

9. The process chamber of claim 1, wherein an electromagnetic field generated by the RF coils exhibits a concentric pattern with respect to a center axis of the coils.

10. The process chamber of claim 1, wherein each RF coil has an RF generator and an impedance matching network for tuning of power delivered to each RF coil.

11. The process chamber of claim 1, wherein an RF generator drives multiple RF coils.

12. A process chamber, comprising:
a chamber body comprising one or more chamber walls and defining a processing region;
an electrostatic chuck comprising a positive electrode and a negative electrode, where a complete circuit is formed between the positive and negative electrodes to provide constant charging to the electrodes; and
two or more inductively driven radio frequency (RF) coils comprising a concentric axial alignment, the RF coils arranged near the chamber walls to strike and sustain a plasma inside the chamber body, wherein at least two of the two or more RF coils are in a recursive configuration.

13. The process chamber of claim 12, wherein at least one of the electrodes comprise multiple pieces of a pattern.

14. The process chamber of claim 12, wherein the RF coils comprise four coils.

15. The process chamber of claim 14, wherein each of the four RF coils are in a series connection.

16. The process chamber of claim 14, wherein each of the four RF coils are in a parallel connection.

17. The process chamber of claim 14, wherein a first set of two RF coils are in a series connection and a second set of two RF coils are in a separate series connection, and the first set is in parallel to the second set.

18. The process chamber of claim 14, wherein a first set of two RF coils are in a parallel connection and a second set of two RF coils are in a separate parallel connection, and the first set is in parallel to the second set.

19. The process chamber of claim 12, wherein each RF coil comprises a single conductor that forms multiple turns or partial turns.

20. A radio frequency (RF) coil configuration, comprising:
two or more RF coils comprising a concentric axial alignment and each having an RF input line and an RF output line, wherein for each input line, there are multiple output lines each having the same length.
